(19) United States
(12) Patent Application Publication
(10) Pub. No.: US 2026/0161246 A1
(43) Pub. Date: Jun. 11, 2026

(54) DISPLAY PANEL AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Xiangdan DONG, Beijing (CN); Tingliang LIU, Beijing (CN); Kemeng TONG, Beijing (CN); Jun YAN, Beijing (CN); Tao HAN, Beijing (CN); Yi HE, Beijing (CN)

(21) Appl. No.: 18/703,827

(22) PCT Filed: Aug. 25, 2023
(86) PCT No.: PCT/CN2023/115090

§ 371 Date: Apr. 23, 2024

(51) Int. Cl. G06F 3/041; G06F 3/044; H10D 86/40; H10D 86/60; H10K 59/12; H10K 59/121; H10K 59/40

(52) U.S. Cl. CPC G06F 3/04164; H10D 86/441; H10D 86/60; H10K 59/1201; H10K 59/1213; H10K 59/40; G06F 3/0445; G06F 2203/04102; G06F 2203/04103; G06F 2203/04111; G06F 2203/04113

(57) ABSTRACT

Provided is a display panel, including: a base substrate, including a display region and a non-display region, wherein the non-display region includes a bendable region and a bonding region; a backplane trace layer, including a first source-drain electrode layer, a first planarization layer, a second source-drain electrode layer, a second planarization layer, and a third source-drain electrode layer that are laminated; a package layer; a touch electrode layer; and a touch trace. The touch trace is disposed in the non-display region and extends through the bendable region to the bonding region. The touch trace includes a first trace portion and a second trace portion. The first trace portion spans the bendable region. The second trace portion is not overlapped with the bendable region. The first trace portion is disposed in the third source-drain electrode layer. The second trace portion is disposed in the touch electrode layer.

### CROSS-REFERENCE TO RELATED APPLICATION

The application is a U.S. national stage of international application No. PCT/CN2023/115090, filed on Aug. 25, 2023, the content of which is herein incorporated by reference in its entirety.

### TECHNICAL FIELD

The present disclosure relates to the field of display technologies, and in particular, relates to a display panel and a method for manufacturing the same, and a display device.

### BACKGROUND

A display device includes a display panel and an integrated circuit (IC). A touch electrode layer in the display panel is connected to a backplane trace layer by a touch trace, and the backplane trace layer is connected to the IC by the touch trace. The backplane trace layer is capable of transmitting a signal from the touch electrode layer to the IC, which allows the IC to determine a touch position in the display panel based on the signal. However, at present, the display panel including the above-mentioned touch electrode layer and the backplane trace layer is implemented in a single way.

### SUMMARY

Embodiments of the present disclosure provide a display panel and a method for manufacturing the same, and a display device. The technical solutions are as follows.

According to some embodiments of the present disclosure, a display panel is provided. The display panel includes:
a base substrate, including a display region and a non-display region surrounding the display region, wherein the non-display region includes a bendable region and a bonding region disposed on a side, away from the display region, of the bendable region;
a backplane trace layer disposed on the base substrate, including a first source-drain electrode layer, a first planarization layer, a second source-drain electrode layer, a second planarization layer, and a third source-drain electrode layer that are laminated;
a package layer disposed on the backplane trace layer;
a touch electrode layer disposed on the package layer, including a touch electrode disposed at least in the display region; and
a touch trace, electrically connected to the touch electrode, wherein the touch trace is disposed in the non-display region and extends through the bendable region to the bonding region, the touch trace includes a first trace portion and a second trace portion that are electrically connected, wherein the first trace portion spans the bendable region, the second trace portion is not overlapped with the bendable region, the first trace portion is disposed in the third source-drain electrode layer, and the second trace portion is disposed in the touch electrode layer.

According to some embodiments of the present disclosure, a method for manufacturing a display panel is provided. The method includes:
providing a base substrate, wherein the base substrate includes:
a display region and a non-display region surrounding the display region, the non-display region including a bendable region and a bonding region disposed on a side, away from the display region, of the bendable region;
forming a backplane trace layer on the base substrate, wherein the backplane trace layer includes a first source-drain electrode layer, a first planarization layer, a second source-drain electrode layer, a second planarization layer, and a third source-drain electrode layer that are laminated;
forming a package layer on a side, away from the base substrate, of the backplane trace layer;
forming a touch electrode layer on a side, away from the base substrate, of the package layer, wherein the touch electrode layer includes a touch electrode disposed at least in the display region; and
providing a touch trace, wherein he touch trace is electrically connected to the touch electrode, the touch trace is disposed in the non-display region and extends through the bendable region to the bonding region, and the touch trace includes a first trace portion and a second trace portion that are electrically connected, wherein the first trace portion spans the bendable region, the second trace portion is not overlapped with the bendable region, the first trace portion is disposed in the third source-drain electrode layer, and the second trace portion is disposed in the touch electrode layer.

According to some embodiments of the present disclosure, a display panel is provided. The display panel includes:
a base substrate including a display region and a non-display region surrounding the display region, wherein the non-display region includes a bendable region and a bonding region disposed on a side, away from the display region, of the bendable region;
a backplane trace layer disposed on the base substrate, including a first source-drain electrode layer, a first planarization layer, a second source-drain electrode layer, a second planarization layer and a third source-drain electrode layer that are laminated;
a package layer disposed on the backplane trace layer;
a touch electrode layer disposed on the package layer, including a touch electrode disposed at least in the display region; and
a touch trace electrically connected to the touch electrode, wherein the touch trace is disposed in the non-display region and extends through the bendable region to the bonding region, and the touch trace includes a first trace portion, a second trace portion, and a third trace portion that are electrically connected, wherein the first trace portion spans the bendable region, the second trace portion is not overlapped with the bendable region, an orthographic projection of the third trace portion on the base substrate is at least partially overlapped with an orthographic projection of the first trace portion on the base substrate, the first trace portion is disposed in the second source-drain electrode layer, the second trace portion is disposed in the touch electrode layer, the third trace portion is disposed in the third source-drain electrode layer, and the first trace portion includes a first sub-portion and a second sub-portion, the second planarization layer isolating the first sub-portion from the third trace portion, and the second sub-portion being electrically connected to the third trace portion by a misaligned via running through the second planarization layer.

According to some embodiments of the present disclosure, a method for manufacturing a display panel is provided. The method includes:
providing a base substrate, wherein the base substrate includes:
a display region and a non-display region surrounding the display region, the non-display region including a bendable region and a bonding region disposed on a side, away from the display region, of the bendable region;
forming a backplane trace layer on the base substrate, wherein the backplane trace layer includes a first source-drain electrode layer, a first planarization layer, a second source-drain electrode layer, a second planarization layer, and a third source-drain electrode layer that are laminated;
forming a package layer on a side, away from the base substrate, of the backplane trace layer;
forming a touch electrode layer on a side, away from the base substrate, of the package layer, wherein the touch electrode layer includes a touch electrode disposed at least in the display region; and
providing a touch trace, wherein the touch trace is electrically connected to the touch electrode, the touch trace is disposed in the non-display region and extends through the bendable region to the bonding region, and the touch trace includes a first trace portion, a second trace portion, and a third trace portion that are electrically connected, wherein the first trace portion spans the bendable region, the second trace portion is not overlapped with the bendable region, and an orthographic projection of the third trace portion on the base substrate is at least partially overlapped with an orthographic projection of the first trace portion on the base substrate, the first trace portion is disposed in the second source-drain electrode layer, the second trace portion is disposed in the touch electrode layer, the third trace portion is disposed in the third source-drain electrode layer, the first trace portion includes a first sub-portion and a second sub-portion, the second planarization layer isolates the first sub-portion from the third trace portion, and the second sub-portion is electrically connected to the third trace portion by a misaligned via running through the second planarization layer.

According to some embodiments of the present disclosure, a display device is provided. The display device includes: a display panel as described above.

### BRIEF DESCRIPTION OF DRAWINGS

For clearer descriptions of the technical solutions in the embodiments of the present disclosure, the following briefly introduces the accompanying drawings to be required in the descriptions of the embodiments. Apparently, the accompanying drawings in the following description show merely some embodiments of the present disclosure, and persons of ordinary skills in the art may still derive other drawings from these accompanying drawings without creative efforts.

FIG. 1 is a schematic structural diagram of a display panel according to some embodiments of the present disclosure;

FIG. 2 is a schematic structural diagram of a cross section of a touch trace region of a display panel according to some embodiments of the present disclosure;

FIG. 3 is a schematic structural diagram of a touch trace according to some embodiments of the present disclosure;

FIG. 4 is a schematic structural diagram of a cross section of a first transition region of a display panel according to some embodiments of the present disclosure;

FIG. 5 is a flowchart of a method for manufacturing a display panel according to some embodiments of the present disclosure;

FIG. 6 is a schematic structural diagram of a cross section of a touch trace region of a display panel according to some embodiments of the present disclosure;

FIG. 7 is a schematic structural diagram of a cross section of a first transition region of a display panel according to some embodiments of the present disclosure;

FIG. 8 is a flowchart of a method for manufacturing a display panel according to some embodiments of the present disclosure; and

FIG. 9 is a schematic structural diagram of a display device according to some embodiments of the present disclosure.

### DETAILED DESCRIPTION

The present disclosure is described in further detail with reference to the accompanying drawings, to clearly present the objects, technical solutions, and advantages of the present disclosure.

It should be noted that the terms “first,” “second,” and the like in the specification of the present disclosure (if present) are used to distinguish similar objects and cannot be used to describe a particular order or sequence. It should be understood that the data used in this way may be interchanged in appropriate circumstances, so that the embodiments of the present disclosure described herein can be implemented in an order other than those illustrated or described herein. The embodiments described in the following exemplary embodiments do not represent all embodiments consistent with the present disclosure. Rather, they are only examples of devices and methods that are consistent with some aspects of the present disclosure.

A display device includes a display panel and an integrated circuit (IC). A touch electrode layer in the display panel is connected to a backplane trace layer, and the backplane trace layer is connected to the IC. The backplane trace layer is capable of conducting a signal from the touch electrode layer to the IC, such that the IC is capable of determining a touch position in the display panel based on the signal. However, at present, the implementation of the display panel including the above-mentioned touch electrode layer and the backplane trace layer is relatively single, and the technical solution provided by the embodiments of the present disclosure enriches the implementation of the display panel.

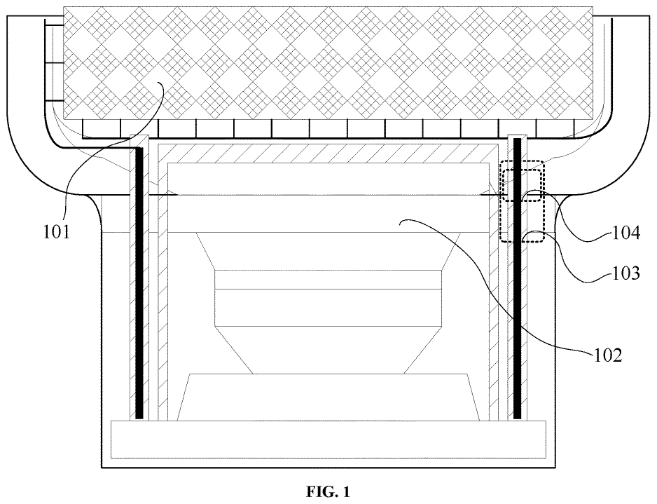

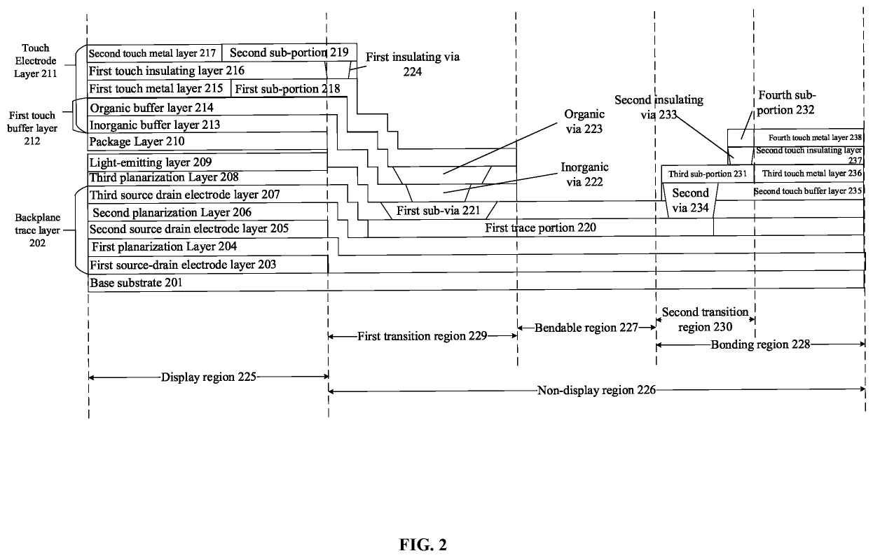

FIG. 1 provides a schematic structural diagram of a display panel including a display region 101 and a bendable region 102. Referring to FIG. 1, touch signals generated by the display region 101 of the display panel are transmitted to a subsequent module through the bendable region 102. A region 103 shown in FIG. 1 includes the bendable region 102 of the display panel and traces of the regions on both sides, and a region 104 shown in FIG. 1 includes traces of the display panel from the display region 101 to the bendable region 102. Referring to FIG. 2, the region shown in FIG. 2 is a schematic structural diagram of the region 103 of FIG. 1, i.e., a schematic structural diagram of a cross section of the touch trace region of the display panel.

In order to enrich the implementation of the touch trace from the display region 225 to the bendable region 227 of the display panel, some embodiments of the present disclosure provide a display panel including a base substrate 201, a backplane trace layer 202, an package layer 210, a touch electrode layer 211, and a touch trace.

The base substrate 201 is a substrate used for manufacturing microelectronic products such as semiconductor devices, electronic components, etc., and the materials of the base substrate 201 include, but are not limited to, monocrystalline silicon, polycrystalline silicon, quartz glass, and alumina ceramics. In the embodiments of the present disclosure, the material of the base substrate 201 is not limited. The base substrate 201 is configured to support and secure structures other than the base substrate 201 disposed on at least one side of the base substrate 201 during the production and manufacturing of the display panel.

Exemplarily, the base substrate 201 includes a display region 225 and a non-display region 226, where the display region 225 is a region in the display panel configured to display an image, and the non-display region 226 is a region in the display panel other than the display region 225. The non-display region 226 includes a bendable region 227 and a bonding region 228 disposed on a side, away from the display region 225, of the bendable region 227. The bendable region 227 is disposed between the display region 225 and the bonding region 228, and is configured to conduct data signals from the display region 225 to the bonding region 228. The biding region 228 includes a plurality of bonding structures, which are configured to connect and correspondingly conduct to pins of a flexible printed circuit (FPC) conduct so as to facilitate the transmission of the corresponding signals. The embodiments of the present disclosure do not limit the connection methods of the bonding structures and the pins.

The backplane trace layer 202 is disposed on a side of the base substrate 201, and the backplane trace layer 202 includes a first source-drain electrode layer 203, a first planarization layer 204, a second source-drain electrode layer 205, a second planarization layer 206, and a third source-drain electrode layer 207 that are laminated. The third source-drain electrode layer 207 is configured to transmit the touch signals in the bendable region 227 in the embodiments of the present disclosure. The materials of the first source-drain electrode layer 203, the second source-drain electrode layer 205, and the third source-drain electrode layer 207 include a metal, an alloy, a metal nitride, an electrically conductive metal oxide, and a transparent conductive material. Each of the first source-drain electrode layer 203, the second source-drain electrode layer 205, and the third source-drain electrode layer 207 is a single-layer or multilayer structure composed of a metal, such as Mo (molybdenum)/Al (aluminum)/Mo or Ti (titanium)/Al/Ti. The materials and compositions of the first source-drain electrode layer 203, the second source-drain electrode layer 205, and the third source-drain electrode layer 207 are not limited herein. The materials of the first planarization layer 204 and the second planarization layer 206 include an organic insulating material, which includes a resin-like material such as polyimide, epoxy resin, acrylic, polyester, photoresist, polyacrylate, polyamide, and silicone, alternatively, the organic insulating material includes an elastomeric material, such as urethane or thermoplastic polyurethane. The materials of the first planarization layer 204 and the second planarization layer 206 are not limited herein

The package layer 210 is disposed on a side, away from the base substrate 201, of the backplane trace layer 202, and the package layer 210 covers an organic light emitting diode in the display region 225 to seal the organic light emitting diode, such that the deterioration of the organic light emitting diode caused by moisture and/or oxygen in the environment is reduced or prevented. The package layer 210 is a single-layer structure or a multi-layer structure including a laminated structure of inorganic and organic layers. For example, the package layer 210 includes a first inorganic package layer, an organic package layer, and a second inorganic package layer successively disposed. The material and compositional structure of the package layer 210 are not limited herein. The material of the package layer 210 includes insulating materials such as silicon nitrogen oxide (SiON), silicon oxide (SiOx), silicon nitride (SiNx), and polymer resin. The inorganic materials such as silicon nitrogen oxide, silicon oxide, silicon nitride prevent intrusion of water and oxygen. The material of the organic package layer is a polymer material containing a desiccant or a polymer material that can block water vapor, such as using a polymer resin to planarize the surface of the display substrate, and to alleviate the stresses of the first inorganic package layer and the second inorganic package layer, and material of the organic package layer includes a desiccant or other water-absorbing materials to absorb substances such as water and oxygen that intrude into the interior.

The touch electrode layer 211 is disposed on a side, away from the base substrate 201 of the package layer 210, and the touch electrode layer 211 is configured to generate a touch signal. The touch signal includes relative position information of the touch, such that the display panel is capable of judging a position of a touch operation according to the relative position information of the touch, and thereby judges the touching intention of the user according to the position of the touch operation, and thus the touch operation and interactive function of the display panel are achieved. The process of generating the touch signal is not limited herein. For example, the touch signal of the touch electrode layer 211 is generated based on a touch structure, which is classified as resistive, capacitive, or infrared according to the operating principle. The composition form of the touch structure is not limited herein.

Exemplarily, the structure of the touch electrode layer 211 includes a first touch buffer layer 212, a first touch metal layer 215, a first touch insulating layer 216, and a second touch metal layer 217 that are laminated on a side, away from the base substrate 201, of the package layer 210. The first touch buffer layer 212 is configured to isolate the first touch metal layer 215 from the package layer 210 and prevent the occurrence of a decrease in material purity caused by the diffusion of substances between the first touch metal layer 215 and the package layer 210. The material of the first touch buffer layer 212 includes, but is not limited to, an inorganic material, such as silicon oxide, silicon nitride, and/or silicon nitride oxide. The material of the first touch buffer layer 212 is not limited herein. In addition, the first touch buffer layer 212 is a single layer or a multilayer. The embodiments of the present disclosure give the description in a scenario where the first touch buffer layer 212 is a single layer as an example. The touch metal layer is a layer structure of the touch electrode layer 211, which is capable of sensing a touch operation and generating a touch signal according to the touch operation.

The first touch insulating layer 216 is provided between the first touch metal layer 215 and the second touch metal layer 217, and the first touch insulating layer 216 is configured to insulate the first touch metal layer 215 and the second touch metal layer 217 from each other. In addition, the first touch insulating layer 216 supports the second touch metal layer 217. In some embodiments, the material of the first touch insulating layer 216 is an organic material, which is a resin-like material such as polyimide, epoxy resin, acrylic, polyester, photoresist, polyacrylate, polyamide, and silicone, alternatively, the organic material is an elastomeric material, such as urethane or thermoplastic polyurethane. The embodiments of the present disclosure do not limit the material of the first touch insulating layer 216.

In some embodiments, the touch electrodes are disposed in the display region 225 and are configured to detect an occurrence of a touch in the display region 225. For example, the touch electrodes include a first touch electrode and a second touch electrode (not shown in the figures). The plurality of first touch electrodes form a first touch electrode line extending in a first direction, and the plurality of second touch electrodes form a second touch electrode line extending in a second direction. The plurality of first touch electrode lines and the plurality of second touch electrode lines are intersected with each other, whereby a touch capacitance is formed at each location where the first touch electrode line and the second touch electrode line are intersected. The touch position is detected by detecting a change in the touch capacitance caused by the proximity of a finger during touch. The display panel includes a plurality of touch signal lines, each of which is configured to be electrically connected to the touch electrode in the display region 225. The touch signal lines include a first touch signal line and a second touch signal line. Each first touch signal line is electrically connected to the first touch electrode line extending in the first direction, and each second touch signal line is electrically connected to the second touch electrode line extending in the second direction. In this way, the touch signal generated by each touch electrode is transmitted to the non-display region 226 of the display panel, and thus to the flexible circuit board, over the touch signal lines.

The touch trace is divided into different portions depending on different display panels, and the embodiments of the present disclosure give the description using a scenario where the touch trace includes a first trace portion 220 and a second trace portion. The touch trace is configured to transmit the touch signal, such that the touch function of the display panel is properly implemented. The first trace portion 220 spans the bendable region 227. That is, the first trace portion 220 is successively provided on a side, close to the display region 225, of the bendable region 227, the bendable region 227, and a side, away from the display region 225, of the bendable region 227, such that the transmission of the touch signal in the bendable region 227 of the display panel is achieved. The second trace portion does not overlap with the bendable region 227. The second trace portion is disposed in the touch electrode layer 211 and is electrically connected to the first trace portion 220. That is, the second trace portion transmits the touch signal of the touch electrode layer 211 in a region other than the bendable region 227 to the first trace portion 220.

By electrically connecting the first trace portion 220 and the second trace portion in the region other than the bendable region 227, a thickness of the bendable region 227 is reduced, and also a situation in which the first trace portion 220 and the second trace portion are electrically disconnected caused by the bending of the bendable region 227 is avoided. The material of the touch trace is not limited herein, which includes, for example, metals, metal alloys, metal nitrides, conductive metal oxides, and transparent conductive materials.

Exemplarily, the first trace portion 220 is disposed in the third source-drain electrode layer 207. The third source-drain electrode layer 207 is disposed between the second planarization layer 206 and the package layer 210, and the third source-drain electrode layer 207 is packaged by the package layer 210. By providing the first trace portion 220 in the third source-drain electrode layer 207, the corrosion of the first trace portion 220 caused by other factors, such as external water vapor is alleviated. The third source-drain electrode layer 207 is disposed in a first transition region 229, a bendable region 227, and a second transition region 230 of the non-display region 226. The first transition region 229 is disposed on a side, close to the display region 225, of the bendable region 227, and the second transition region 230 is disposed on a side, away from the display region 225, of the bendable region 227. In the embodiment of the present disclosure, a layer change of the trace, i.e., a connection of the trace between different layers, is performed in the first transition region 229 and the second transition region 230. For example, in the first transition region 229, the touch signal is transmitted from the touch electrode layer 211 to the first trace portion 220 disposed in the third source-drain electrode layer 207 referred herein, and in the second transition region 230, the touch signal is transmitted to the subsequent module, such that the signal is transmitted to the FPC.

In some embodiments of the present disclosure, the transmission of the touch signal in the first transition region 229 and the second transition region 230 is performed relying on an electrical connection of the touch trace, and the electrical connection of the touch trace is realized by a first via in the first transition region 229 and a second via 234 in the second transition region 230. The embodiments of the present disclosure give the description using the layer change of the trace in the first transition region 229 as an example, and the layer change of the trace in the second transition region 230 refers to that in the first transition region 229. Therefore, the via referred hereinafter are the first via of the first transition region 229, and the first via includes a first sub-via 221, an inorganic via 222, and an organic via 223.

Exemplarily, in the first transition region 229, the first trace portion 220 in the third source-drain electrode layer 207 is capable of being electrically connected to the second trace portion (including a first sub-portion 218 and a second sub-portion 219). The display panel is bent in the bendable region 227, and the third source-drain electrode layer 207 needs to ensure that it does not break in the bendable region 227. The material of the third source-drain electrode layer 207 includes a metal, an alloy, a metal nitride, an electrically conductive metal oxide, and a transparent electrically conductive material. For example, the third source-drain electrode layer 207 is a single layer or a multilayer composed of a metal, such as Mo/Al/Mo or Ti/Al/Ti. The material of the third source-drain electrode layer 207 is not limited herein.

Exemplarily, the second trace portion is disposed in the first touch metal layer 215 and/or the second touch metal layer 217. The second trace portion is electrically connected to the first trace portion 220 by a second sub-via (222, 223) running through the first touch buffer layer 212. In some embodiments, the second trace portion includes the first sub-portion 218 disposed in the first touch metal layer 215, and the second sub-portion 219 disposed in the second touch metal layer 217. The first sub-portion 218 and the second sub-portion 219 are electrically connected by a first insulating via 224 at the first touch insulating layer 216, such that the transmission resistance of the touch trace is reduced.

The electrical connection is not limited herein. For example, the material of the second trace portion is deposited at the second sub-via, such that the second trace portion is electrically connected to the first trace portion 220, or there is a via connection component is present at the second sub-via, such that the second trace portion is electrically connected to the via connection component, and the via connection component is electrically connected to the first trace portion 220. The material of the via connection component is not limited, as long as the touch signal is transmitted between the second trace portion and the first trace portion 220.

In some embodiments, the display panel according to the embodiments of the present disclosure further includes a light-emitting layer 209, and a third planarization layer 208 disposed between the light-emitting layer 209 and the third source-drain electrode layer 207. The via runs through the third planarization layer 208. The light-emitting layer 209 includes a small-molecule organic material or a polymer-molecule organic material, and a fluorescent light-emitting material or a phosphorescent light-emitting material, and emits red light, green light, blue light, and white light. Further, as desired, the light-emitting layer 209 includes a hole injection layer, a hole transmission layer, an electron injection layer, an electron transmission layer, and the like. The structure and material of the light-emitting layer 209 are not limited herein. The third planarization layer 208 is disposed on a side, away from the base substrate 201, of the third source-drain electrode layer 207.

Exemplarily, the third planarization layer 208, the first touch buffer layer 212, the first touch metal layer 215, the first touch insulating layer 216, and the second touch metal layer 217 are present in the same display panel. On the basis that the second trace portion is electrically connected to the first trace portion 220 by the via running through the first touch buffer layer 212 and the first touch insulating layer 216, the first sub-via 221 disposed in the third planarization layer 208 is present. The second trace portion is also electrically connected to the first trace portion 220 by the first sub-via 221. That is, the first sub-portion 218 of the second trace portion is electrically connected to the second sub-portion 219 by the first insulating via 224 running through the first touch insulating layer 216 of the touch electrode layer 211. The first insulating via 224 is disposed in a side, close to the display region 225, of the first via, and the first sub-portion 218 is electrically connected to the first trace portion 220 by the via running through the first touch buffer layer 212 and the first sub-via 221.

Exemplarily, the material of the third planarization layer 208 includes an organic insulating material that includes, for example, a resin-like material such as polyimide, epoxy, acrylic, polyester, photoresist, polyacrylate, polyamide, and silicone. Further, the organic insulating material includes an elastomeric material such as urethane and thermoplastic polyurethane. The material of the third planarization layer 208 is the same as or different from the material of the first planarization layer 204 and the second planarization layer 206. The first sub-via 221 is present in the third planarization layer 208, and the first sub-via 221 is configured to provide a pathway for the electrical connection of the second trace portion and the first trace portion 220 in the first transition region 229.

Exemplarily, the first touch buffer layer 212 and the third planarization layer 208 both include an organic insulating layer, the vias include the first sub-via 221 in the third planarization layer 208, the second sub-via in the first touch buffer layer 212, and the insulating via 224 running through the first touch insulating layer 216. The first sub-via 221 is larger than the second sub-via. Each of the first touch buffer layer 212 and the third planarization layer 208 is a multilayer structure, which includes the organic insulating layer. The material of the organic insulating layer includes, for example, resin-based materials such as polyimide, epoxy, acrylic, polyester, photoresist, polyacrylate, polyamide, and silicone or, for example, elastomeric materials such as urethane and thermoplastic polyurethane.

Exemplarily, the first touch buffer layer 212 includes an inorganic buffer layer 213 and an organic buffer layer 214 that are laminated and disposed on the side, away from the base substrate 201, of the package layer 210. The second sub-via in the first touch buffer layer 212 is divided into an inorganic via 222 in the inorganic buffer layer 213 and an organic via 223 in the organic buffer layer 214, based on the two layers of the inorganic buffer layer 213 and the organic buffer layer 214. The organic via 223 is larger than the inorganic via 222. The relative sizes of the vias are defined based on the design features of the display panel, and the sizes of the vias referred herein are illustrative.

Exemplarily, in the embodiments of the present disclosure, the second trace portion disposed in the first touch metal layer 215 is referred to as the first sub-portion 218, and the second trace portion disposed in the second touch metal layer 217 is referred to as the second sub-portion 219. In the first transition region 229, the first sub-portion 218 and the second sub-portion 219 are electrically connected to each other by the first insulating via 224 in the first touch insulating layer 216, which facilitates the implementation of functions that the first touch metal layer 215 and the second touch metal layer 217 transmit the same touch signal as described above. The first sub-portion 218 of the second trace portion is electrically connected to the first trace portion 220 disposed in the third source-drain electrode layer 207 by the second sub-via (including the inorganic via 222 and the organic via 223) running through the first touch buffer layer 212, and the first sub-via 221 running through the third planarization layer 208.

Exemplarily, the first trace portion 220 disposed in the third source-drain electrode layer 207 achieves a layer change in the second transition region 230. The embodiments of the present disclosure do not limit the layer change in the second transition region 230, as long as the touch signal of the first trace portion 220 is transmitted to the next film laye. The embodiments of the present disclosure give the description using the layer change of the first trace portion 220 in the second transition region 230 and the third trace portion 220 as an example. The third trace portion 220 includes a third sub-portion 231 disposed in the third touch metal layer 236 and a fourth sub-portion 232 disposed in the fourth touch metal layer 238. The first touch metal layer 215 is in the same layer as the third touch metal layer 236, and the second touch metal layer 217 is in the same layer as the fourth touch metal layer 238. After the layer change of the trace in the second transition region 230 is completed, the touch signal is transmitted to the subsequent modules including the FPC, such that the transmission of the touch signal is achieved. The structure involved in the subsequent transmission process is not limited herein, as long as the touch signal is conducted to the IC outside the display panel.

In some embodiments, in the second transition region 230, the first trace portion 220 is electrically connected to the third trace portion of the touch trace by the second via 234, and the third trace portion is disposed in the touch electrode layer of the second transition region 230. The structure of the touch electrode layer of the second transition region 230 is referenced to the structure of the touch electrode layer 211 of the display region 627, which is not repeated herein. The third trace portion includes a third sub-portion 231 and a fourth sub-portion 232 that are connected in parallel. The third sub-portion 231 is disposed in the third touch metal layer 236 of the touch electrode layer, and the fourth sub-portion 232 is disposed in the fourth touch metal layer 238 of the touch electrode layer. In the second transition region 230, the third sub-portion 231 is electrically connected to the fourth sub-portion 232 by a second insulating via 233 running through the second touch insulating layer 237 of the touch electrode layer. The second insulating via 233 is disposed in a side, away from the display region 225, of the second via 234. The third sub-portion 231 is electrically connected to the first trace portion 220 by the second via 234 running through the second touch buffer layer 235 and the third planarization layer 208.

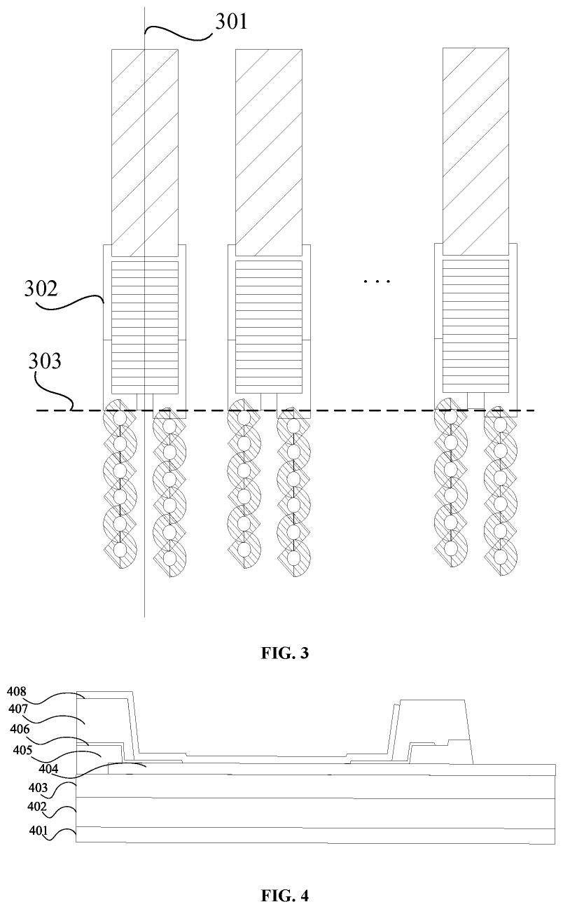

Referring to the schematic structural diagram of the touch trace shown in FIG. 3, the schematic structural diagram of the touch trace shown in FIG. 3 illustrates a region 104 in FIG. 1. Taking a cross-section along a position 301 shown in FIG. 3, a region 302 is the first transition region disposed on the side, close to the display region, of the bendable region, and a line 303 is an intersection line between the first transition region and the bendable region, and thus the structural diagram of the cross section of the first transition region of the display panel as shown in FIG. 4 is acquired.

Exemplarily, the cross-section diagram shown in FIG. 4 corresponds to the first transition region 229 shown in FIG. 2. 401 in FIG. 4 corresponds to the base substrate 201 in FIG. 2. 402 corresponds to the first planarization layer 204 in FIG. 2. 403 corresponds to the second planarization layer 206 in FIG. 2. 404 corresponds to the third source-drain electrode layer 207 in FIG. 2. 405 corresponds to the third planarization layer 208 in FIG. 2. 406 corresponds to the inorganic buffer layer 213 in FIG. 2. 407 corresponds to the organic buffer layer 214 in FIG. 2. 408 corresponds to the second trace portion (including the first sub-portion 218 and the second sub-portion 219) in FIG. 2. The second trace portion 408 is electrically connected to the first trace portion disposed in the third source-drain electrode layer 404 at the location shown in FIG. 4 by the organic via of the organic buffer layer 407, the inorganic via of the inorganic buffer layer 406, and the first sub-via of the third planarization layer 405.

In summary, some embodiments of the present disclosure provide a display panel. By disposing the first trace portion of the touch trace in the third source-drain electrode layer, the touch electrode layer in the display panel is connected to the third source-drain electrode layer in the backplane trace layer by the touch trace instead of the second source-drain electrode layer. The third source-drain electrode layer is connected to the IC by the touch trace, such that the need to form vias in the middle layers of the second source-drain layer and the third source-drain layer is avoided, which reduces the thickness of the film layer that needs to have vias therein, and thus the problem that the vias cannot be formed due to the thickness of the film layer is avoided. In addition, the reduction of the thickness of the film layer that needs to have vias therein improves the removal rate of residual adhesive after exposure and other processes at the via location, thereby avoiding the problem of circuit connection failure due to residual adhesive.

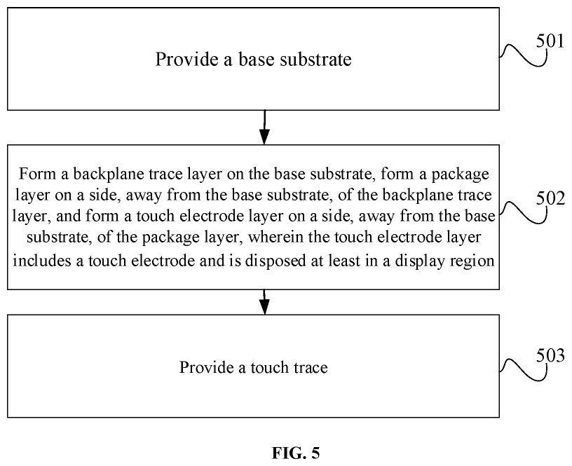

Based on the display panel according to the above-described embodiments of the disclosure, see FIG. 5, some embodiments of the present disclosure provide a method of manufacturing a display panel. The method includes step 501 to step 503.

In step 501, a base substrate is provided.

The base substrate is a type of substrate used for manufacturing a microelectronic product such as a semiconductor device or an electronic component, and the material of the base substrate includes, but is not limited to, monocrystalline silicon, polycrystalline silicon, quartz glass, and alumina ceramics. In the embodiments of the present disclosure, the material of the base substrate is not limited. The base substrate is configured to support and secure structures other than the base substrate disposed on at least one side of the base substrate during the production and manufacturing of the display panel.

Exemplarily, the base substrate includes a display region and a non-display region. The display region configured to display images, and the non-display region is a region in the display panel other than the display region. The non-display region includes a bendable region and a bonding region disposed on a side, away from the display region, of the bendable region. The bendable region is disposed between the display region and the bonding region and is configured to conduct data signals from the display region to the bonding region. The bonding region includes a plurality of bonding structures, and the bonding structures are configured to correspondingly conduct and connect to pins in the FPC so as to facilitate transmission of the corresponding signals. The connection methods of the bonding structures and the pins are not limited herein.

In step 502, a backplane trace layer is formed on the base substrate, a package layer is formed on a side, away from the base substrate, of the backplane trace layer, and a touch electrode layer is formed on a side, away from the base substrate, of the package layer, wherein the touch electrode layer includes a touch electrode and is disposed at least in a display region.

The backplane trace layer includes a first source-drain electrode layer, a first planarization layer, a second source-drain electrode layer, a second planarization layer, and a third source-drain electrode layer provided that are laminated.

Exemplarily, the manner in which the source-drain electrode layer is formed is not limited herein. The planarization layer is deposited on a side, away from the base substrate, of the formed first source-drain electrode layer, a first planarization film covering the first planarization layer is formed on a side, away from the base substrate, of the first planarization layer, and photoresist is deposited on the first planarization film. The class of photoresist is not limited herein. A mask plate is used to expose the photoresist. The mask plate is a grey mask plate or a halftone mask plate. The mask plate includes a fully light transmissive region, a partially light transmissive region, and an opaque region. A transmittance of the partially transmissive region is less than a transmittance of the fully transmissive region, and thus during the exposure process, a portion, corresponding to the fully transmissive region, of the photoresist is fully exposed, a portion, corresponding to the partially transmissive region, of the photoresist is partially exposed, and a portion, corresponding to the opaque region, of the photoresist is not exposed.

Exemplarily, the photoresist is developed to acquire a photoresist pattern that includes a fully removed region corresponding to the opaque region, a partially retained region corresponding to the partially transmissive region, and a fully retained region corresponding to the fully transmissive region. The first planarization film is etched using this photoresist pattern. For example, a portion, corresponding to the fully removed region, of the first planarization film is completely etched away; next, a greying process is performed on the photoresist pattern, such that the photoresist in the fully retained region is thinned and the photoresist in the partially retained region is completely removed. Then, a portion, corresponding to the partially retained region, of the first planarization film is etched away, and finally, the remaining photoresist is stripped. Ultimately, the first planarization layer is acquired. The methods for forming the second source-drain electrode layer, the second planarization layer, and the third source-drain electrode layer are referred to the above description of the scheme, which are not repeated herein.

Exemplarily, the package layer is disposed on a side, away from the base substrate, of the backplane trace layer, and the package layer covers an organic light-emitting diode in the display region to seal the organic light-emitting diode, such that deterioration of the organic light emitting diode caused by moisture and/or oxygen in the environment is reduced or prevented.

Exemplarily, the touch electrode is disposed in the display region and is configured to detect an occurrence of a touch in the display region. The touch electrode layer is disposed on a side, away from the base substrate, of the package layer, and the touch electrode layer is configured to generate a touch signal. The touch signal includes relative position information of the touch, such that the display panel is capable of judging a position of a touch operation based on the relative position information of the touch, thereby judges an intention of the user to touch based on the position of the touch operation, and thereby realizing the touch operation of the display panel as well as the interactive function. The touch buffer layer is configured to isolate the first touch metal layer and the package layer, preventing the occurrence of a decrease in material purity caused by the diffusion of substances between the first touch metal layer and the package layer.

In step 503, a touch trace is provided.

Providing the touch traces means transmitting the touch signal through the trace in the original display panel. In the embodiments of the present disclosure, the first trace portion of the touch trace is disposed in the third source-drain electrode layer, and the second trace portion of the touch traces is disposed in the touch electrode layer. In this way, the transmission of touch signal in the display panel provided in the above embodiments is achieved. For the specific transmission path, reference is made to the relevant description of the display panel, which is not limited herein.

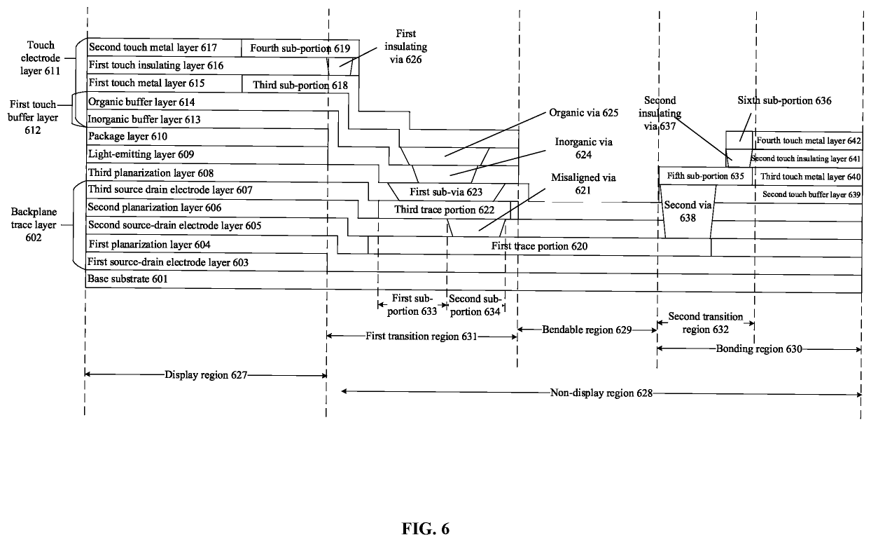

Referring to FIG. 6, the region shown in FIG. 6 is a structural schematic diagram of the region 103 in FIG. 1, i.e., a cross-section of the touch trace region of the display panel.

In order to enrich the implementation of the touch trace from the display region 627 to the bendable region 629 of the display panel, some embodiments of the present disclosure provide another display panel including a base substrate 601, a backplane trace layer 602, a package layer 610, a touch electrode layer 611, and a touch trace.

The structures and compositions of the base substrate 601, the backplane trace layer 602, the first source-drain electrode layer 603, the first planarization layer 604, the second planarization layer 606, the third source-drain electrode layer 607, and the package layer 610 are referred to the descriptions in the above embodiments, which are not repeated herein. In addition, the structures and compositions of the base substrate 601, the backplane trace layer 602, and the package layer 610 mentioned herein are only illustrative, and the structures capable of satisfying the relevant functions of the embodiments of the present disclosure, other than those mentioned herein, shall also be within the scope of protection of the embodiments of the present disclosure.

Exemplarily, the touch trace mentioned in the embodiments of the present disclosure is electrically connected to the touch electrode, and the touch trace is at least partially disposed in the non-display region 628 and extends to the bonding region 630 through the bendable region 629. The touch trace is divided into different portions according to different display panels. The embodiments of the present disclosure give the description using a scenario where the touch trace includes a first trace portion 620, a second trace portion, and a third trace portion 622 that are electrically connected as an example.

Exemplarily, the touch trace is configured to transmit a touch signal from the touch electrode layer 611, such that the touch function of the display panel is properly implemented. The first trace portion 620 spans the bendable region 629. That is, the first trace portion 620 is at least capable of connecting a side, close to the display region 627, of the bendable region 629 to a side, away from the display region 627, of the bendable region 629, and thus the transmission of the touch signal in the bendable region 629 of the display panel is achieved. The second trace portion does not overlap with the bendable region 629. That is, the second trace portion is disposed in a region outside the bendable region 629. An orthographic projection of the third trace portion 622 on the base substrate 601 is at least partially overlapped with an orthographic projection of the first trace portion 620 on the base substrate 601. That is, there exists a portion of the third trace portion 622 that is disposed in the same region as the first trace portion 620, it may be that an orthographic projection of a portion of the third trace portion 622 on the base substrate 601 is within the orthographic projection of the first trace portion 620 on the base substrate 601; or an orthographic projection of the entirety of the third trace portion 622 on the base substrate 601 is within the orthographic projection of the first trace portion 620 on the base substrate 601; or the orthographic projection of the first trace portion 620 on the base substrate 601 is within the orthographic projection of the third trace portion 622 on the base substrate 601, which is not limited herein. The material of the touch trace is not limited herein, which includes, for example, metals, metal alloys, metal nitrides, conductive metal oxides, and transparent conductive materials.

Exemplarily, the first trace portion 620 is disposed in the second source-drain electrode layer 605, and the second source-drain electrode layer 605 is disposed between the first planarization layer 604 and the second planarization layer 606. The second source-drain electrode layer 605 is disposed in a first transition region 631, a bendable region 629, and a second transition region 632 of the non-display region 628. The first transition region 631 is disposed on a side, close to the display region 627, of the bendable region 629, and the second transition region 632 is disposed on a side, away from the display region 627, of the bendable region 629. In the embodiment of the present disclosure, a layer change of the trace, i.e., the connection of the trace between different layers, is performed in the first transition region 631 and the second transition region 632. For example, in the first transition region 631, a touch signal from the touch electrode layer 611 is transmitted to the third trace portion 622 disposed in the third source-drain electrode layer 607 as mentioned in the embodiments of the present disclosure, the touch signal is transmitted from the third trace portion 622 disposed in the third source-drain electrode layer 607 to the first trace portion 620 disposed in the second source-drain electrode layer 605, and the touch signal is transmitted to a subsequent module in the second transition region 632, such that the signal is transmitted to the FPC.

In some embodiments of the present disclosure, the transmission of the touch signal in the first transition region 631 and the second transition region 632 is performed relying on an electrical connection of the touch trace, and the electrical connection of the touch trace is realized by a first via formed in the first transition region 631 and a second via 638 disposed in the second transition region 632. The embodiments of the present disclosure give the description using the layer change of the trace in the first transition region 631 as an example, and the layer change of the trace in the second transition region 632 refers to that in the first transition region 631. Therefore, the vias referred hereinafter are first vias in the first transition region 631. A misaligned via 621 corresponds to the second sub-portion 634 of the first trace portion 620, and the third trace portion 622 is electrically connected to the second sub-portion 634 of the first trace portion 620 by the misaligned via 621.

Exemplarily, the second trace portion is disposed in the first touch metal layer 615 and/or the second touch metal layer 617. The second trace portion is electrically connected to the third trace portion 622 by a second sub-via (624, 625) running through the first touch buffer layer 612. In some embodiments, the second trace portion includes a third sub-portion 618 disposed in the first touch metal layer 615 and a fourth sub-portion 619 disposed in the second touch metal layer 617. The third sub-portion 618 and the fourth sub-portion 619 are electrically connected by a first insulating via 626 in the first touch insulating layer 616, such that the transmission resistance of the touch trace is reduced.

The manner of electrical connection is not limited herein. For example, the material of the second trace portion is deposited at the via, such that the second trace portion is electrically connected to the third trace portion 622, or there is a via connection component at the via, such that the second trace portion is electrically connected to the via connection component, and the via connection component is electrically connected to the third trace portion 622. The material of the via connection component is not limited herein, as long as the touch signal is transmitted between the second trace portion and the third trace portion 622.

Exemplarily, the third trace portion 622 in the third source-drain electrode layer 607 is capable of being electrically connected to the second trace portion in the first transition region 631. The display panel is bent in the bendable region 629, and the second source-drain electrode layer 605 needs to be ensured that it does not break in this region. The material of the second source-drain electrode layer 605 includes a metal, an alloy, a metal nitride, an electrically conductive metal oxide, and a transparent electrically conductive material. For example, the second source-drain electrode layer 605 is a single layer or a multilayer structure composed of a metal, such as Mo/Al/Mo or Ti/Al/Ti. The material of the second source-drain electrode layer 605 is not limited herein.

Exemplarily, the first trace portion 620 is divided into a first sub-portion 633 and a second sub-portion 634. The second planarization layer 606 isolates the first sub-portion 633 from the third trace portion 622, and the second sub-portion 634 is electrically connected to the third trace portion 622 by the misaligned via 621 running through the second planarization layer 606. The second planarization layer 606 is disposed between the first trace portion 620 and the third trace portion 622. The material of the second planarization layer 606 includes an organic insulating material including a resin-like material such as a polyimide, an epoxy resin, an acrylic, a polyester, a photoresist, a polyacrylate, a polyamide, and a silicone. Further, the organic insulating material includes elastomeric materials such as urethane and thermoplastic polyurethane. The second planarization layer 606 isolates the first sub-portion 633 of the first trace portion 620 from the third trace portion 622 in a defined region where the transmission of the touch signal is prevented. The misaligned via 621 formed in a region, corresponding to the second sub-portion 634 of the first trace portion 620, of the second planarization layer 606 provides a pathway for the electrically connection between the second sub-portion 634 of the first trace portion 620 and the third trace portion 622, such that the touch signal is transmitted from the third trace portion 622 to the first trace portion 620 by the misaligned via 621.

In some embodiments, the display panel provided by some embodiments of the present disclosure further includes a light-emitting layer 609, and a third planarization layer 608 disposed between the light-emitting layer 609 and the third source-drain electrode layer 607. The first sub-via 623 runs through the third planarization layer 608. The material of the light-emitting layer 609 includes a small molecule organic material or a polymer molecule organic material, a fluorescence light emitting material, or a phosphorescent light-emitting material, which emits red light, green light, blue light, white light, and the like. Further, as desired, the light-emitting layer 609 includes a hole injection layer, a hole transmission layer, an electron injection layer, an electron transmission layer, and the like. The structure and material of the light-emitting layer 609 are not limited herein. The third planarization layer 608 is disposed on a side, away from the base substrate 601, of the third source-drain electrode layer 607. The material of the third planarization layer 608 is the same as or different from the materials of the first planarization layer 604 and the second planarization layer 606. A first sub-via 623 is present in the third planarization layer 608, and the first sub-via 623 is configured to provide a pathway for the electrical connection between the second trace portion and the third trace portion 622 in the first transition region 631.

Exemplarily, the third planarization layer 608, the first touch buffer layer 612, the first touch metal layer 615, the first touch insulating layer 616, and the second touch metal layer 617 are present in the same display panel. On the basis that the second trace portion is electrically connected to the third trace portion 622 by the via running through the first touch buffer layer 612 and the first touch insulating layer 616, a second sub-via 623 disposed in the third planarization layer 608 is present. The second trace portion is also electrically connected to the third trace portion 622 by the first sub-via 623. That is, the third sub-portion 618 of the second trace portion is electrically connected to the fourth sub-portion 619 by a first insulating via 626 running through the first touch insulating layer 616 of the touch electrode layer 611. The first insulating via 626 is disposed in a side, close to the display region 627, of the first via, and the third sub-portion 618 is electrically connected to the third trace portion 622 by the via running through the first touch buffering layer 612 and the first sub-via 623.

Exemplarily, the first touch buffer layer 612 and the third planarization layer 608 both include an organic insulating layer, and the vias include a first sub-via 623 disposed in the third planarization layer 608 and a second sub-via formed in the first touch buffer layer 612. The first sub-via 623 is larger than the second sub-via. Each of the first touch buffer layer 612 and the third planarization layer 608 is a multilayer structure, which includes the organic insulating layer. The material of the organic insulating layer includes, for example, a resinous material such as polyimide, epoxy, acrylic, polyester, photoresist, polyacrylate, polyamide, or silicone, alternatively, an elastomeric material such as urethane or thermoplastic polyurethane.

Exemplarily, the first touch buffer layer 612 includes an inorganic buffer layer 613 and an organic buffer layer 614 that are laminated and disposed on a side, away from the base substrate 601, of the package layer 610. The second sub-via formed in the first touch buffer layer 612 is divided into an inorganic via in the inorganic buffer layer 613 and an organic via 625 in the organic buffer layer 614 based on the inorganic buffer layer 613 and the organic buffer layer 614. The organic via 625 is larger than the inorganic via 624. The relative sizes of the vias are defined based on the design features of the display panel, and the sizes of the vias mentioned in the embodiments of the present disclosure are illustrative.

Exemplarily, in some embodiments, the second trace portion includes a third sub-portion 618 disposed in the first touch metal layer 615 and a fourth sub-portion 619 disposed in the second touch metal layer 617. In the first transition region 631, the third sub-portion 618 and the fourth sub-portion 619 are electrically connected by the first insulating via 626 of the first touch insulating layer 616, which facilitates the realization of the function that the first touch metal 615 layer and the second touch metal layer 617 transmit the same touch signal as the describe above. The third sub-portion 618 of the second trace portion is electrically connected to the third trace portion 622 disposed in the third source-drain electrode layer 607 by the second sub-via (including the inorganic via 624 and the organic via 625) running through the first touch insulating layer 616 and the first sub-via 623 running through the third planarization layer 608, and the third trace portion 622 disposed in the third source-drain electrode layer 607 is electrically connected to the second sub-portion 634 of the first trace portion 620 disposed in the second source-drain electrode layer 605 by the misaligned via 623 running the second planarization layer 606.

Exemplarily, the first trace portion 620 disposed in the second source-drain electrode layer 605 achieves a layer change in the second transition region 632, and the embodiments of the present disclosure do not limit the layer change in the second transition region 632, as long as the touch signal of the first trace portion 620 is transmitted to the next film layer. The embodiments of the present disclosure give the description using the layer change of the first trace portion 620 in the second transition region 632 and the fourth trace portion as an example. The fourth trace portion includes a fifth sub-portion 635 disposed in the third touch metal layer 640 and a sixth sub-portion 636 disposed in the fourth touch metal layer 642, wherein the first touch metal layer 615 is in the same layer as the third touch metal layer 640, and the second touch metal layer 617 is in the same layer as the fourth touch metal layer 642. After the layer change of the trance in the second transition region 632 is completed, the touch signal is transmitted to the subsequent module including the FPC, thereby realizing the transmission of the touch signal. The embodiments of the present disclosure do not limit the structure involved in the subsequent transmission process, as long as the touch signal is conducted to the IC outside the display panel.

In some embodiments, in the second transition region 632, the first trace portion 620 is electrically connected to the fourth trace portion of the touch trace by the second via 638, and the fourth trace portion is disposed in the touch electrode layer of the second transition region 632. The structure of the touch electrode layer of the second transition region 632 is referred to the structure of the touch electrode layer 611 of the display region 627, which is not repeated herein. The fourth trace portion includes a fifth sub-portion 635 and a sixth sub-portion 636 that are connected in parallel. The fifth sub-portion 635 is disposed in the third touch metal layer 640 of the touch electrode layer, and the sixth sub-portion 636 is disposed in the fourth touch metal layer 642 of the touch electrode layer. In the second transition region 632, the fifth sub-portion 635 is electrically connected to the sixth sub-portion 636 by a second insulating via 637 running through the second touch insulating layer 641 of the touch electrode layer, and the second insulating via is disposed in a side, away from the display region 627, of the second via 638. The fifth sub-portion 635 is electrically connected to the first trace portion 620 by the second via 638 running through the second touch buffer layer 639, the third planarization layer 608, and the second planarization layer 606.

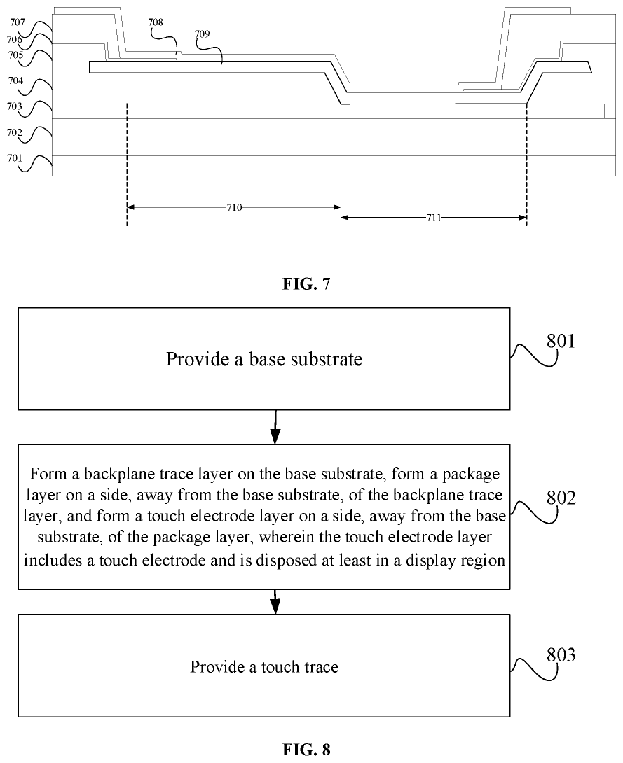

Referring to the structural schematic of the touch trace shown in FIG. 3, the structural schematic of the touch trace shown in FIG. 3 illustrates the region 104 in FIG. 1. Using a cross-section along a position 301 shown in FIG. 3, wherein 302 is a first transition region on a side, close to the display region, of the bendable region, a structural schematic of a cross-section of the first transition region of the display panel shown in FIG. 7 is acquired.

Exemplarily, the cross-section diagram shown in FIG. 7 corresponds to the first transition region 631 shown in FIG. 6. 701 in FIG. 7 corresponds to the base substrate 601 in FIG. 6; 702 corresponds to the first planarization layer 604 in FIG. 6; 703 corresponds to the second source-drain electrode layer 605 in FIG. 6; 704 corresponds to the second planarization layer 606 in FIG. 6; 705 corresponds to the third planarization layer 608 in FIG. 6; 706 corresponds to the inorganic buffer layer 613 in FIG. 6; 707 corresponds to the organic buffer layer 614 in FIG. 6; 708 corresponds to the second trace portion (including the third sub-portion 618 and the fourth sub-portion 619) in FIG. 6; 709 corresponds to the third source-drain electrode layer 607 in FIG. 6; 710 corresponds to a region where the first sub-portion 633 of the first trace portion 620 is disposed; and 711 corresponds to a region where the second sub-portion 634 of the first trace portion 620 is disposed. The second trace portion 708 is electrically connected to the third trace portion disposed in the third source-drain electrode layer 709 by the organic via of the organic buffering layer 707, the inorganic via of the inorganic buffering layer 706, and the first sub-via of the third planarization layer 705 in the first region 710, and the third trace portion disposed in the third source-drain electrode layer 709 is electrically connected to the first trace portion disposed in the second source-drain electrode layer 703 by the misaligned via formed in the second planarization layer 704 in the second region 711.

In summary, some embodiments of the present disclosure provide a display panel. The first trace portion of the touch trace is disposed in the second source-drain electrode layer, the second trace portion is disposed in the touch electrode layer, the third trace portion is disposed in the third source-drain electrode layer, the first trace portion includes the first sub-portion and the second sub-portion, the second planarization layer separates the first sub-portion from the third trace portion, and the second sub-portion is electrically connected to the third trace portion by a misaligned via running through the second planarization layer. In this way, the touch signal is transmitted from the second trace portion to the third trace portion and then to the first trace portion, such that the touch signal is transmitted to the IC.

Based on the display panel described above, referring to FIG. 8, the embodiments of the present disclosure provide a method for manufacturing a display panel. The method includes step 801 to step 803.

For the contents of step 801 and step 802, reference is made to step 501 and step 502 described above, which are not repeated herein.

In step 803, a touch trace is provided.

Providing the touch traces means transmitting the touch signal through the trace in the original display panel. In the embodiments of the present disclosure, a first trace portion of the touch traces is disposed in a second source-drain electrode layer, a second trace portion of the touch trace is disposed in a touch electrode layer, and a third trace portion of the touch trace is disposed in a third source-drain electrode layer. In addition, the first trace portion includes a first sub-portion and a second sub-portion, the second planarization layer isolates the first sub-portion from the third trace portion, and the second sub-portion is electrically connected to the third trace portion by a misaligned via running through the second planarization layer. In this way, the transmission of the touch signal in the display panel provided in the above embodiments is achieved. The specific transmission path is detailed in the relevant description of the display panel described above, which are not repeated herein.

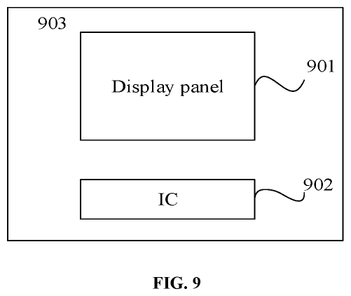

Referring to FIG. 9, some embodiments of the present disclosure provide a display device 903 including any of the display panels 901 described above. In addition to this, the display device 903 includes an IC 902 to achieve a response to a touch signal of the display panel 901 in the display device 903.

It should be understood that the term “plurality” referred herein means two or more. The term “and/or” describes the relationship of the associated objects, indicating that three types of relationships can exist. For example, A and/or B means: A exists alone, both A and B exist, and B alone exists. The symbol “/” generally indicates that the associated objects are in an “or” relationship.

Described above are only exemplary embodiments, which are not intended to limit the present application, and any modifications, equivalent substitutions, or improvements made within the principles of the present application shall be included in the scope of protection of the present application.

1. A display panel, comprising:
a base substrate, comprising a display region and a non-display region surrounding the display region, wherein the non-display region comprises a bendable region and a bonding region disposed on a side, away from the display region, of the bendable region;
a backplane trace layer disposed on the base substrate, comprising a first source-drain electrode layer, a first planarization layer, a second source-drain electrode layer, a second planarization layer, and a third source-drain electrode layer that are laminated;
a package layer disposed on the backplane trace layer;
a touch electrode layer disposed on the package layer, comprising a touch electrode disposed at least in the display region; and
a touch trace, electrically connected to the touch electrode, wherein the touch trace is disposed in the non-display region and extends through the bendable region to the bonding region, the touch trace comprises a first trace portion and a second trace portion that are electrically connected, wherein the first trace portion spans the bendable region, the second trace portion is not overlapped with the bendable region, the first trace portion is disposed in the third source-drain electrode layer, and the second trace portion is disposed in the touch electrode layer.

2. The display panel according to claim 1, wherein
the touch electrode layer comprises a first touch buffer layer, a first touch metal layer, a first touch insulating layer, and a second touch metal layer successively laminated on a side, away from the base substrate, of the package layer; and
the second trace portion is disposed in the first touch metal layer and/or the second touch metal layer, and the second trace portion is electrically connected to the first trace portion by a via running through the first touch buffer layer and the first touch insulating layer.

3. The display panel according to claim 1, further comprising: a light-emitting layer, and a third planarization layer disposed between the light-emitting layer and the third source-drain electrode layer; wherein a first sub-via is formed in the third planarization layer, and the second trace portion being electrically connected to the first trace portion by the first sub-via.

4. The display panel according to claim 1, wherein the non-display region comprises a first transition region and a second transition region that are adjacent to the bendable region; wherein
the first transition region is disposed on a side, close to the display region, of the bendable region, the second transition region is disposed on a side, away from the display region, of the bendable region, a first via is formed in the first transition region, and a second via is formed in the second transition region, the touch electrode layer is disposed in the second transition region, the second trace portion is electrically connected to the first trace portion by the first via, and the first trace portion is electrically connected to a third trace portion of the touch trace by the second via, the third trace portion being disposed in the touch electrode layer in the second transition region.

5. The display panel according to claim 3, wherein the first touch buffer layer of the touch electrode layer and the third planarization layer both comprise an organic insulating layer, and the non-display region comprises a first transition region adjacent to the bendable region, wherein the first transition region is disposed on a side, close to the display region, of the bendable region, a first via is formed in the first transition region, the first via comprising the first sub-via formed in the third planarization layer and the second sub-via formed in the first touch buffer layer, the second trace portion is electrically connected to the first trace portion by the first sub-via and the second sub-via, and the first sub-via is larger than the second sub-via.

6. The display panel according to claim 5, wherein the first touch buffer layer comprises an inorganic buffer layer and an organic buffer layer that are successively laminated, the second sub-via comprises an inorganic via formed in the inorganic buffer layer and an organic via formed in the organic buffer layer, and the second trace portion is electrically connected to the first trace portion by the inorganic via, the organic via, and the first sub-via, the organic via being larger than the inorganic via.

7. The display panel according to claim 4, wherein the second trace portion comprises a first sub-portion and a second sub-portion that are connected in parallel, wherein the first sub-portion is disposed in a first touch metal layer of the touch electrode layer, and the second sub-portion is disposed in a second touch metal layer of the touch electrode layer; in the first transition region, the first sub-portion is electrically connected to the second sub-portion by a first insulating via running through the first touch insulating layer of the touch electrode layer, the first insulating via being formed in a side, close to the display region, of the first via; and the first sub-portion is electrically connected to the first trace portion by the first via.

8. (canceled)

9. A display panel, comprising:
a base substrate comprising a display region and a non-display region surrounding the display region, wherein the non-display region comprises a bendable region and a bonding region disposed on a side, away from the display region, of the bendable region;
a backplane trace layer disposed on the base substrate, comprising a first source-drain electrode layer, a first planarization layer, a second source-drain electrode layer, a second planarization layer, and a third source-drain electrode layer that are laminated;
a package layer disposed on the backplane trace layer;
a touch electrode layer disposed on the package layer, comprising a touch electrode disposed at least in the display region; and
a touch trace electrically connected to the touch electrode, wherein the touch trace is disposed in the non-display region and extends through the bendable region to the bonding region, and the touch trace comprises a first trace portion, a second trace portion, and a third trace portion that are electrically connected, wherein the first trace portion spans the bendable region, the second trace portion is not overlapped with the bendable region, an orthographic projection of the third trace portion on the base substrate is at least partially overlapped with an orthographic projection of the first trace portion on the base substrate, the first trace portion is disposed in the second source-drain electrode layer, the second trace portion is disposed in the touch electrode layer, the third trace portion is disposed in the third source-drain electrode layer, and the first trace portion comprises a first sub-portion and a second sub-portion, the second planarization layer isolating the first sub-portion from the third trace portion, and the second sub-portion being electrically connected to the third trace portion by a misaligned via running through the second planarization layer.

10. The display panel according to claim 9, wherein the touch electrode layer comprises a first touch buffer layer, a first touch metal layer, a first touch insulating layer, and a second touch metal layer that are successively laminated on a side, away from the base substrate, of the package layer, the second trace portion is disposed in the first touch metal layer and/or the second touch metal layer, and the second trace portion is electrically connected to the third trace portion by a via running through the first touch buffer layer and the first touch insulating layer.

11. The display panel according to claim 9, further comprising: a light-emitting layer and a third planarization layer disposed between the light-emitting layer and the third source-drain electrode layer; wherein a first sub-via is formed in the third planarization layer, and the second trace portion is electrically connected to the third trace portion by the first sub-via.

12. The display panel according to claim 9, wherein the non-display region comprises a first transition region and a second transition region that are adjacent to the bendable region, wherein the first transition region is disposed on a side, close to the display region, of the bendable region, the second transition region is disposed on a side, away from the display region, of the bendable region, a first sub-via is formed in the first transition region, a second sub-via is formed in the second transition region, the touch electrode layer is disposed in the second transition region, the second trace portion is electrically connected to the third trace portion by the first via, and the first trace portion is electrically connected to a fourth trace portion of the touch trace by the second via, the fourth trace portion being disposed in the touch electrode layer in the second transition region.

13. The display panel according to claim 11, wherein the first touch buffer layer of the touch electrode layer and the third planarization layer both comprise an organic insulating layer, and the non-display region comprises a first transition region adjacent to the bendable region, wherein the first transition region is disposed on a side, close to the display region, of the bendable region, and a first via is formed in the first transition region, wherein the first via comprises the first sub-via formed in the third planarization layer and the second sub-via formed in the first touch buffer layer, and the second trace portion is electrically connected to the third trace portion by the first sub-via and the second sub-via, the first sub-via being larger than the second sub-via.

14. The display panel according to claim 13, wherein the first touch buffer layer comprises an inorganic buffer layer and an organic buffer layer that are laminated, the second sub-via comprises an inorganic via formed in the inorganic buffer layer and an organic via formed in the organic buffer layer, and the second trace portion is electrically connected to the third trace portion by the inorganic via, the organic via, and the first sub-via, the first sub-via being larger than the second sub-via.

15. The display panel according to claim 12, wherein the second trace portion comprises a third sub-portion and a fourth sub-portion that are connected in parallel, wherein the third sub-portion is disposed in a first touch metal layer of the touch electrode layer, and the fourth sub-portion is disposed in a second touch metal layer of the touch electrode layer; in the first transition region, the third sub-portion is electrically connected to the fourth sub-portion by a first insulating via running through the first touch insulating layer of the touch electrode layer, the first insulating via being disposed in a side, close to the display region, of the first via; and the third sub-portion is electrically connected to the third trace portion by the first via.

16. (canceled)

17. A display device, comprising: a display panel; wherein the display panel comprises:
a base substrate, comprising a display region and a non-display region surrounding the display region, wherein the non-display region comprises a bendable region and a bonding region disposed on a side, away from the display region, of the bendable region;
a backplane trace layer disposed on the base substrate, comprising a first source-drain electrode layer, a first planarization layer, a second source-drain electrode layer, a second planarization layer, and a third source-drain electrode layer that are laminated;
a package layer disposed on the backplane trace layer;
a touch electrode layer disposed on the package layer, comprising a touch electrode disposed at least in the display region; and
a touch trace, electrically connected to the touch electrode, wherein the touch trace is disposed in the non-display region and extends through the bendable region to the bonding region, the touch trace comprises a first trace portion and a second trace portion that are electrically connected, wherein the first trace portion spans the bendable region, the second trace portion is not overlapped with the bendable region, the first trace portion is disposed in the third source-drain electrode layer, and the second trace portion is disposed in the touch electrode layer.

18. The display device according to claim 17, wherein the touch electrode layer comprises a first touch buffer layer, a first touch metal layer, a first touch insulating layer, and a second touch metal layer successively laminated on a side, away from the base substrate, of the package layer, the second trace portion is disposed in the first touch metal layer and/or the second touch metal layer, and the second trace portion is electrically connected to the first trace portion by a via running through the first touch buffer layer and the first touch insulating layer.

19. The display device according to claim 17, wherein the display panel further comprises: a light-emitting layer, and a third planarization layer disposed between the light-emitting layer and the third source-drain electrode layer; wherein a first sub-via is formed in the third planarization layer, and the second trace portion being electrically connected to the first trace portion by the first sub-via.

20. A display device, comprising: the display panel as defined in claim 9.

21. The display device according to claim 20, wherein the touch electrode layer comprises a first touch buffer layer, a first touch metal layer, a first touch insulating layer, and a second touch metal layer that are successively laminated on a side, away from the base substrate, of the package layer, the second trace portion is disposed in the first touch metal layer and/or the second touch metal layer, and the second trace portion is electrically connected to the third trace portion by a via running through the first touch buffer layer and the first touch insulating layer.

22. The display device according to claim 20, wherein the display panel further comprises: a light-emitting layer and a third planarization layer disposed between the light-emitting layer and the third source-drain electrode layer; wherein a first sub-via is formed in the third planarization layer, and the second trace portion is electrically connected to the third trace portion by the first sub-via.
